(19) United States
(12) Patent Application Publication
(10) Pub. No.: US 2003/0226077 A1
(43) Pub. Date: Dec. 4, 2003

(54) Low power level-sensitive scan mechanism

(75) Inventors: Victor V. Zyuban, Peekskill, NY (US); David J. Meltzer, Wappingers Falls, NY (US)

Correspondence Address: Eric W. Petraske, 68 Old Hawleyville Road, Bethel, CT, 06801, US

(73) Assignee: INTERNATIONAL BUSINESS MACHINES CORPORATION, Armonk, NY

(21) Appl. No.: 10/156,900

(22) Filed: May 28, 2002

(51) Int. Cl. G01R 31/28

(52) U.S. Cl. 714/726

(57) ABSTRACT

A latch suitable for an integrated circuit having a test mechanism that involves scanning a set of logic circuits has a two-stage main latch and a level-sensitive scan latch, the combination operating normally as a single-phase latch and as a master-slave latch during scan mode. The scan mechanism is introduced at the second stage of the main latch, with the result that the capacitance introduced by the scan connection switches at most once per clock cycle, reducing the power load of the circuit; and the scan latch output is separated from the data output of the main latch, thereby further reducing the power load.

### FIELD OF THE INVENTION

The field of the invention is low power CMOS logic integrated circuits, in particular a circuit for a flip-flop designed to be testable with the Level Sensitive Scan Design (LSSD) methodology.

### BACKGROUND OF THE INVENTION

As integrated circuits become more complex, they become more difficult to test. A complex digital circuit is typically sequential; i.e. it consists of combinatorial logic, memory elements, some primary inputs, and some outputs. Testing an integrated circuit involves applying a test vector at the primary inputs and observing the responses at the primary outputs. To fully test an integrated circuit, a set of test vectors must be generated such that possible faults at all the circuit's internal nodes can be detected by observing responses. This is made difficult by the inadequacy of access provided by the limited number of externally controllable primary inputs and externally observable primary outputs. Further, it is made even more difficult by the presence of internal memory elements such as flip-flops and feedback in the logic.

To make the testing of a complex integrated circuit manageable, the circuit can be designed to provide for access to all of the memory elements of the circuit by making the flip-flops scannable. In a scannable memory element, a second scan input to each flip-flop is provided and is connected to an output of another flip-flop, so that all flip-flops form a shift register, as well as performing their functions in the circuit.

The scan feature can be used in testing a circuit as follows. A test vector is shifted into the shift register formed by the flip-flops of the circuit. The circuit is then operated for one or more cycles in the normal operation mode. The resulting states of all flip-flops of the circuit are then read out from the shift register formed by the flip-flops. Thus, the use of scannable flip-flops converts the difficult problem of testing a sequential circuit to the easier problem of testing a combinatorial circuit.

There are two major approaches to building scannable designs: edge-triggered and level sensitive, LSSD scan (Level Sensitive Scan Design). Because the LSSD scan is race free, it is more robust than the edge-triggered scan, and it preserves the integrity of the scan chain even in the presence of significant clock skews, which typically get worse at reduced power supply voltages. Since power supply reduction is essential for reducing power dissipation, the fully static LSSD scan mechanism is the one that is the most suitable for low-power designs. However, the power overhead of the level-sensitive scannable design may be very significant. For example, some studies have reported a 54% increase in power of an LSSD standard cell design over the identical non-scannable design.

The standard way of implementing an LSSD master-slave latch is shown in FIGS. 1A and 1B for the transmission-gate latch (often called PowerPC latch in the literature), and NORA latch (often called C\hat{ }2 MOS latch in the literature). In these latches the extra capacitance introduced by the scan mechanism that switches in the normal operation mode (referred in the claims as “introduced capacitance”) consists of the following components:

C_scan_int, capacitance introduced inside the latch, is the drain capacitance of transistors N1 and P1 (which are cut off in the normal operation mode), C_scan_int=2 Cd, and C_scan_out, capacitance introduced at the latch output, is the sum of the gate capacitance of the input transistors in the next latch of the scan chain (not shown in the figure) which are connected to node Q of FIGS. 1A and 1B, and the capacitance of the wire that connects latches in the scan chain, which is also connected to the output node Q of FIG. 1A and 1B. Thus, the total capacitance introduced at the output of the latch is C_scan_out=2C_g+C_scan_wire.

The length of the scan wire can be quite small (10 micron to 20 micron in a 0.13 micron technology) between adjacent latches in custom datapath multi-bit registers, however it is much longer (several hundred um in 0.13 micron technology) for wires that connect the scan output of the last latch in a multi-bit register with the scan input of the first latch in the next multi-bit register in the scan chain. Moreover, extra buffering may be required to decouple the capacitance of the long scan wire from the datapath. Also, the scan wire capacitances are much higher in ASIC designs.

The capacitance of the scan mechanism C_scan_out, introduced at the latch output, is charged/discharged during the normal operation mode every time the output of the latch changes, leading to the power overhead of the scan mechanism in the normal operation mode P_scan_out=0.5*f*a*Vdd\hat{ }2*C_scan_out, per latch. In this formula, Vdd is the power supply voltage, f is the clocking rate, and a is the data switching factor (0<a<1).

The capacitance of the scan mechanism C_scan_int, introduced inside the latch, is charged/discharged during the normal operation mode every time the input of the latch changes, and clock C is high. Thus, glitches (level changes at the data input occurring when clock C is high), cause charge/discharge of the capacitance introduced inside the latch, C_scan_int. This leads to the power overhead of the scan mechanism in the normal operation mode P_scan_int=0.5*f*(a+b)*Vdd\hat{ }2*C_scan_int, per latch. In this formula, Vdd is the power supply voltage, f is the clocking rate, a is the data switching factor (0<a<1), and b is the glitching factor at the latch input.

The total power overhead of the traditional scan mechanism in the normal operation mode is the sum of the two components, P_scan=P_scan_int+P_scan_out. P_scan_out=0.5*f*(a+b)*Vdd\hat{ }2*2Cd+0.5*f*a*Vdd\hat{ }2*(2C_g+C_scan_wire).

For a typical low power microprocessor with 30,000 latches, running at f=400 MHz at V_dd=1.2V the power overhead of the standard scan mechanism is approximately 50 mW, or even higher, which may not be negligible in state of the art low power designs.

Even if the power overhead of the conventional scan mechanism is tolerable, the scannable latches in FIG. 1 require two phases of clock, clock C and clock B, in the normal operation mode, which increases the total power of the clocking system in a low-power microprocessor by 15% to 30%.

As an example of a low-power single-phase flip-flop, FIG. 2 shows a conventional edge triggered, single clock phase, non scannable, sense amplifier latch. This latch has been used in low power processors because of its low power operation. The design shown in FIG. 2 is not scannable, however.

A prior art scannable version of the sense amplifier latch is shown in FIGS. 3A and 3B. For the design in FIG. 3A, the latch has an extra input, called Scan, to control the operating mode of the latch. During the normal mode of operation the input signal Scan is low, and the sense amplifier current flows through transistors N1 or N2, whose gates are controlled by the input data signals D and Db (using the convention that a lower case b indicates the logic complement). During the scan-in mode the signal Scan is high, and the sense amplifier current flows through transistors N3 or N4, whose gates are controlled by the scan-in signals I and Ib. The rising edge of clock C causes one of the outputs (51 or 52 in FIG. 3A) of the first stage (referred in the claims as “data control subcircuit”) of the latch to go low, depending on the signal at the scan data inputs I and Ilb. If input I is high and Ib is low, then the rising edge of the clock will enable the current path to the ground, and cause node 51 go low. If I is low and Ib is high, then at the rising clock edge node 52 will go low. Nodes 51 and 52 are set and reset inputs of the second stage of the latch, formed by two cross-coupled NAND gates (referred in the claims as “memory subcircuit”). Low level at node 51 sets the second stage (or memory subcircuit) of the latch to ‘1’, and low level at node 52 sets the second stage of the latch to ‘0’.

This conventional implementation of the scan-in capability is compact, but has a very high power overhead, because it significantly increases capacitance at the bottom part (data control subcircuit) of the latch (nodes 10, 20, 30, 40 and 50). Since these nodes are charged and discharged every clock cycle, independent of the data switching activity, the increase in power dissipation due to the scan mechanism per latch equals P_scan=f*Vdd (Vdd-Vt)*C_scan, where C_scan is the capacitance introduced by the scan mechanism at nodes 10, 20, 30, 40 and 50 in FIG. 3A. In this formula, Vdd is the power supply voltage, f is the clocking rate of the processor.

FIG. 3B shows an alternative implementation of the scan-in capability by means of multiplexing the input data and the scan-in data. This approach significantly degrades the performance of the latch by increasing the setup time. Moreover, it leads to an increase in power dissipation, which is proportional to the sum of the input data switching activity and the glitching factor,

P_scan_int=0.5*f*(a+b)*Vdd\hat{ }2*C_scan, per latch. In this formula, Vdd is the power supply voltage, f is the clocking rate, C_scan is the capacitance of the multiplexor, a is the data switching factor (0<a<1), and b is the glitching factor at the latch input, that is the average number of spurious transitions in a clock cycle.

The two methods described above for adding the scan feature to the sense amplifier latch are not compatible with the Level-Sensitive Scannable Design (LSSD) methodology. During the scan mode the latching of the scan-in data is edge-driven rather than level-driven, as required by LSSD. As an example, the last two described methods do not allow testing the design in the transparency mode, when both clock A and B are asserted high simultaneously.

The art needs low-power scannable latches for testing purposes and connected with low power designs.

### SUMMARY OF THE INVENTION

The present invention relates to a low-power LSSD-scannable CMOS flip-flop that operates as a single-phase latch during the normal mode, and as a master-slave LSSD-compatible latch during the scan mode.

A feature of the invention is the incorporation of the scan-in mechanism in the second stage (referred to as “memory subcircuit”) of the flip-flop so that the introduced capacitance of the scan circuitry is decoupled from the switching activity at the data input, thereby significantly reducing the power overhead imposed by the scan feature.

Another feature of the invention is the separation of the scan output of the flip-flop from the data output, which prevents the wire connecting latches in the scan chain from toggling in the normal operation mode and therefore further reduces the power overhead.

### BRIEF DESCRIPTION OF THE DRAWING

These and other features, objects, and advantages of the present invention will become apparent upon consideration of the following detailed description of the invention when read in conjunction with the drawing in which:

FIG. 1A shows a transmission-gate scannable latch circuit of the prior art.

FIG. 1B shows a NORA scannable latch circuit of the prior art.

FIG. 2 shows a conventional edge triggered single clock phase non scannable sense amplifier latch of the prior art.

FIG. 3A shows a scannable version of a sense amplifier latch of the prior art.

FIG. 3B shows a multiplexer-based scannable version of a sense amplifier latch of the prior art.

FIG. 4A shows a block diagram of a scan mechanism according to the invention.

FIG. 4B shows waveforms for proper operation of the scan mechanism of FIG. 4A.

FIG. 5 shows the connection of the scannable latches of FIG. 4A in a scan chain.

FIG. 6A shows an embodiment of the scan mechanism with a two-stage master-slave latch.

FIG. 6B shows an embodiment of the scan mechanism with a two-stage edge-triggered flip-flop.

FIG. 7 shows another embodiment with a two-stage flip-flop, in which the memory subcircuit is a SR (Set-Reset) latch.

FIG. 8 shows the embodiment of FIG. 7, with a sense-amplifier flip-flop.

FIG. 9 shows another version of the embodiment of FIG. 7, with a true single phase latch in the first stage, and a RAM-style latch in the memory subcircuit.

FIG. 10 shows an embodiment of the scan mechanism with a particular type of a pulsed latch.

FIG. 11 shows circuit embodiments of the scan mechanism with several types of commonly used flip-flops.

### DETAILED DESCRIPTION

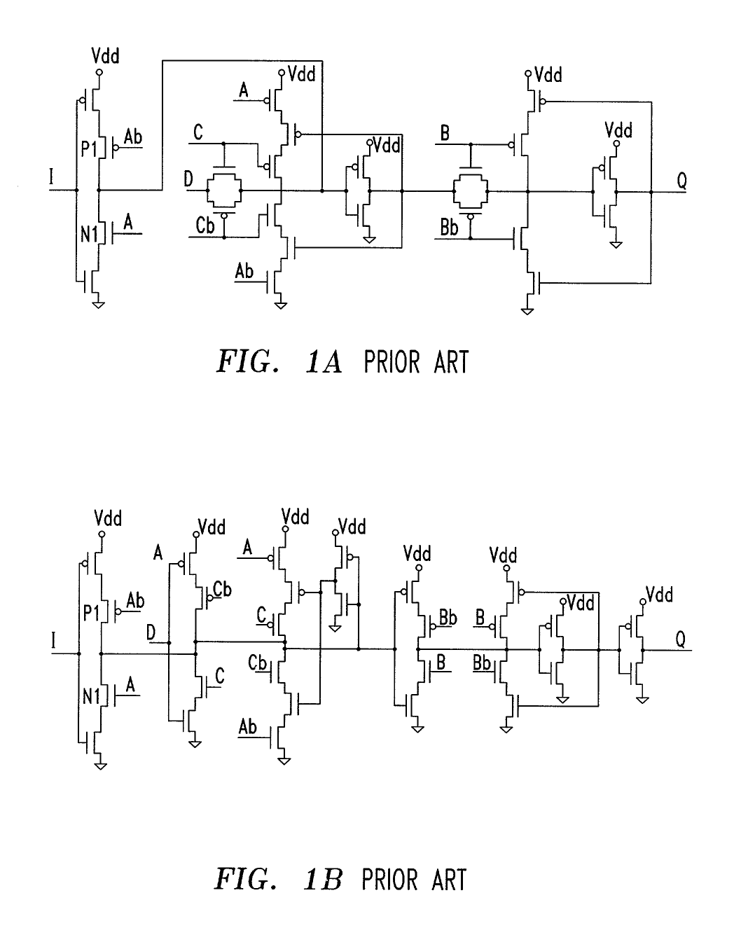

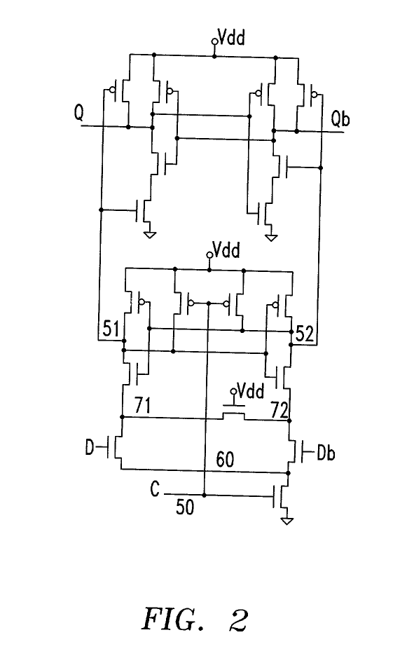

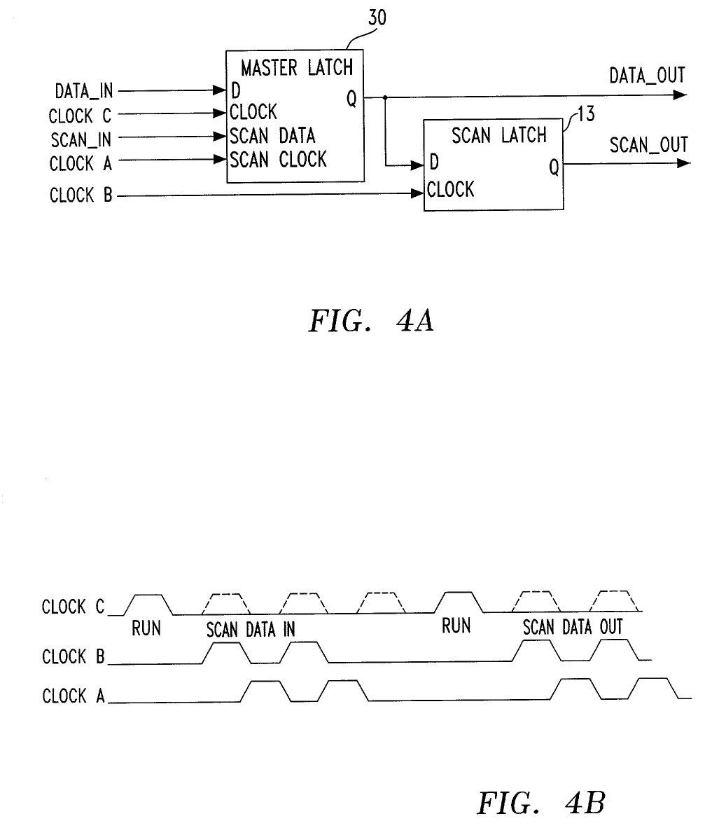

FIG. 4A shows a block diagram of a low power scan latch according to the invention. The scannable latch in FIG. 4A consists of the master latch 30 and the scan latch 13. It has the same set of inputs as the conventional scannable latch of the prior art in FIGS. 1A and 1B; however, unlike the conventional latch it has separate outputs for data and scan signals. The data output feeds circuits or another latch down the pipeline and scan output is connected to the scan input of another latch in the scan chain or to the testing circuitry.

The master latch in FIG. 4A is a fast latch that operates during the normal operation mode as a single-phase latch controlled by clock C. During the scan mode the master latch works as a transparent latch controlled by clock A. It can be any type of a single phase latch, or a two-phase latch, for example, edge-triggered latch, pulsed latch, or dual edge triggered flip-flop. The scan latch is a low-area slow level-sensitive latch, controlled by clock B. Any type of a level sensitive latch can be used for the scan latch. The output of the scan latch is the scan output of the entire flip-flop.

FIG. 4B shows the timing diagram of the clock signals for the proper operation of the circuit in FIG. 4A in the scan and regular operation modes. During normal operation mode, clock A and clock B are kept at the low level, and the flip-flop works as a conventional latch, while scan latch 13 is in the non-transparent state, so that the scan output does not toggle, and the internal capacitances inside the scan latch do not toggle either. This reduces the power dissipation in the normal operation mode. During the scan mode, clock C is kept at the low level, and the flip-flop works as a master-slave latch, controlled by nonoverlapping clocks A and B, providing a robust, level-sensitive scan operation. The described scan mechanism also allows testing the design in the transparency mode, when both clock A and B are asserted high simultaneously (not shown in FIG. 4A).

The low power overhead in the normal operation mode is achieved in part by separating the scan output of the latch from the data output, so that the wire connecting latches in the scan chain does not toggle in the normal operation mode, and in part by decoupling the capacitance introduced by the scan mechanism from the data inputs of the latch, so that it is not charged/discharged by glitches at the data input. Since the described latch operates with a single phase of clock during the normal operation mode the power penalty of driving and distributing the second clock phase is avoided, whereas during the scan mode the latch operates as a master-slave latch with two nonoverlapping clock phases, as required by the LSSD standard.

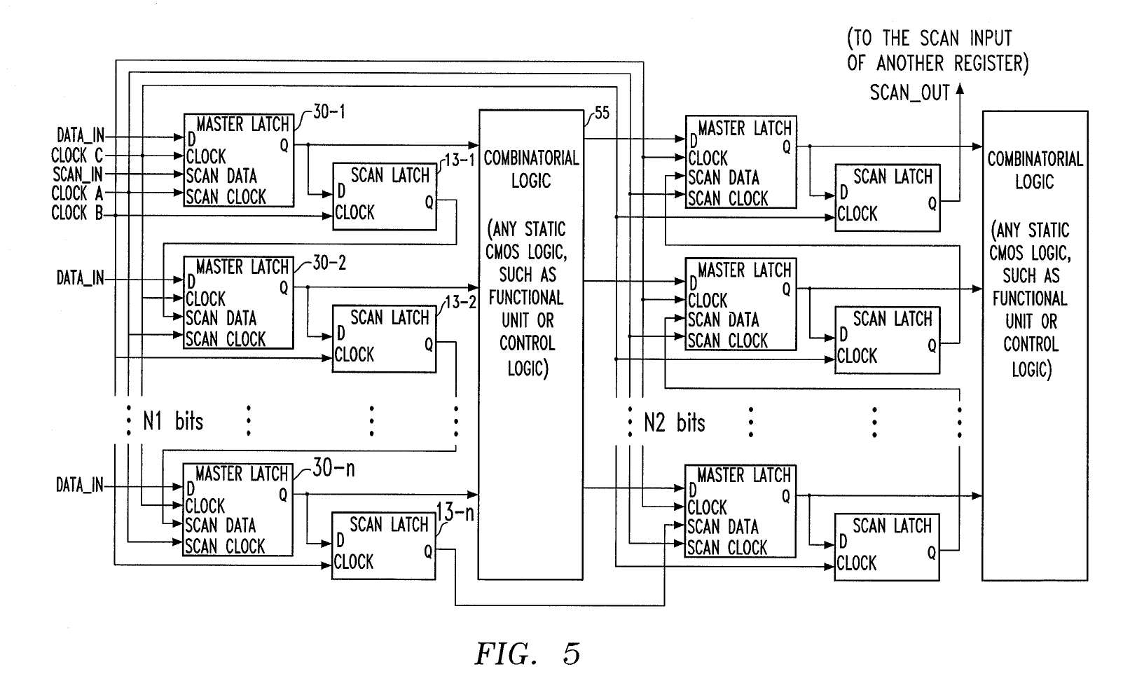

FIG. 5 shows the connection of scannable latches into the scan chain. The data outputs of every latch 30-i are connected to the inputs to the combination logic 55, which can be a functional unit, or a piece of control logic, or just a set of wires that pass data from inputs to the outputs. The scan inputs and scan outputs of the latches are connected into one or multiple scan chains (e.g. output of 13-1 is connected to the input of 30-2), according to conventional techniques. Either single-rail or dual-rail signal can be used for connecting latches in the scan chain. In the scan mechanism described in this disclosure only one clock (clock C) is used in the normal operation mode while clocks A and B are kept at the low level, which prevents wires that connect latches in the scan chain from switching and, thus, saves power.

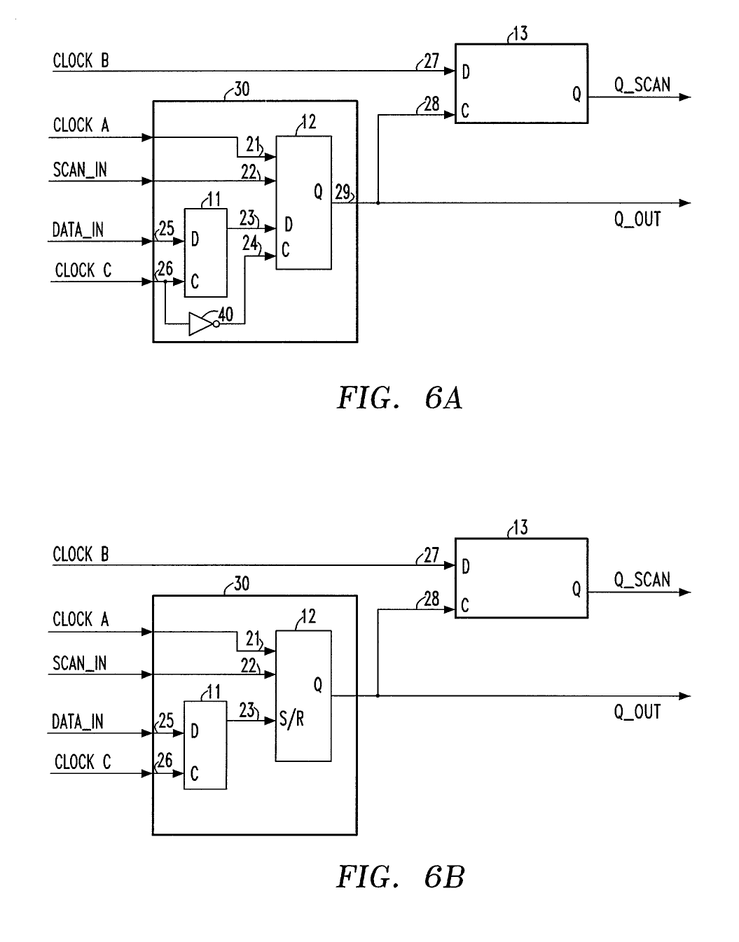

FIG. 6A shows an embodiment of the inventive scan mechanism with a commonly used two-stage master-slave latch. In this embodiment the main latch 30 consists of two level sensitive latches 11 and 12 (master and slave) which are controlled by clock C and its complement. The main latch 30 in FIG. 6A differs from the prior art latch in FIGS. 1A or 1B by the connection of the scan input SCAN_IN. In the conventional implementation of FIGS. 1A and 1B the scan input is multiplexed with the data input at the first stage (data control subcircuit) of the latch (11 in FIG. 6A), whereas in the inventive latch in FIG. 6A the scan input is multiplexed with the data signal at the second stage (memory subcircuit) of the latch (12 in FIG. 6A). Such a connection decouples the capacitance introduced by multiplexing the scan and data signals from the glitching activity at the data input. In the inventive mechanism this capacitance switches only when the output of the latch Q_OUT switches to a new value (which may happen at most once per clock cycle), while in the conventional implementation the introduced capacitance switches whenever the input of the latch switches and clock C is high (which typically happens multiple times per clock cycle, especially at the outputs of complex functional units). This leads to power savings during the normal operation mode. During the scan mode, the level sensitive scan latch 13 prevents the scan input SCAN_IN from propagating directly to the scan output Q_SCAN, eliminating the possibility for race conditions in the scan mode.

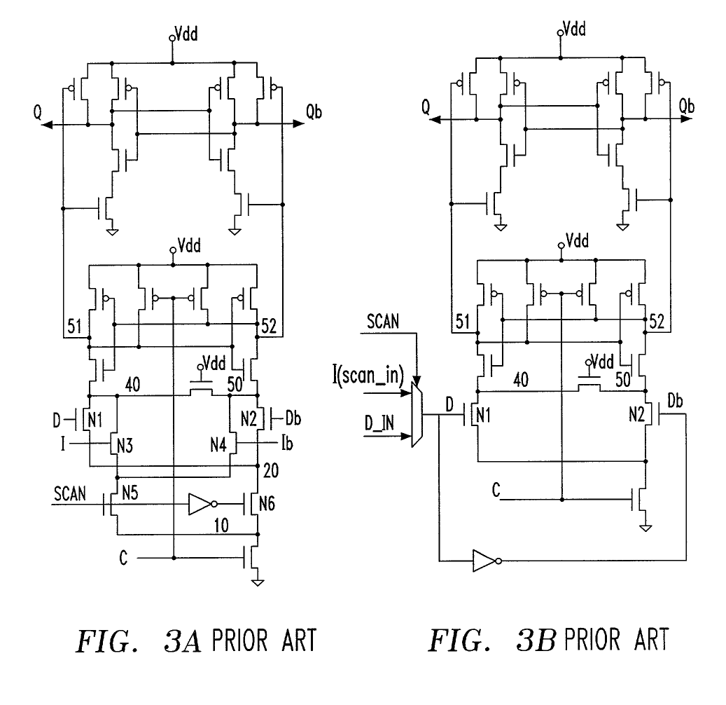

FIG. 6B shows an embodiment of the inventive scan mechanism of FIG. 4A with an edge-triggered flip-flop or pulsed latch used for the main latch 30. The main latch consists of two subcircuits: memory subcircuit 12 that holds the state of the latch and data control subcircuit 11 that generates a signal to set or reset memory subcircuit 12 (in other words, write new data to subcircuit 12). All commonly used edge-triggered and pulsed latches can be represented as such. The Set/Reset signal 23 generated by data control subcircuit 11 can be either a single-rail or a dual-rail signal of either polarity, it can also be a pair of independent Set and Reset signals. The scheme in FIG. 6B differs from commonly used scannable edge-triggered or pulsed latch, such as those in FIGS. 3A and 3B in that the scan input is multiplexed with the data signal at the memory subcircuit 12 of the latch. Such a connection decouples the capacitance introduced by multiplexing the scan and data signals from the glitching activity at the data input, which leads to power reduction, as described above. During the scan mode, the level sensitive scan latch 13 prevents the scan input SCAN_IN from propagating directly to the scan output Q_SCAN, eliminating the possibility of race conditions in the scan mode.

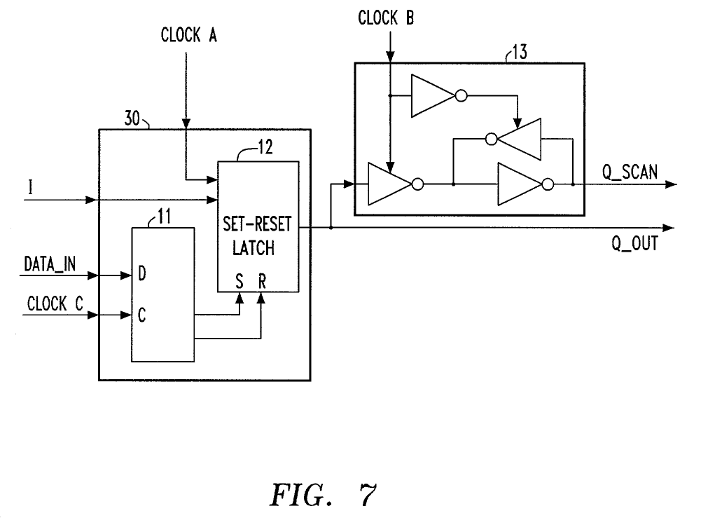

FIG. 7 shows an embodiment of the scannable latch of FIG. 6B with a Set Reset latch used in the second stage 12 (memory subcircuit) of the main latch 30. In this embodiment the memory subcircuit 12 holds the state of the latch, and it changes the state in response to an assertion of the Set or Reset signals (with either low or high active level). The first stage 11 (data control subcircuit) generates the Set and Reset signals, in response to changes at the data input and clock, using one of conventional techniques. The first stage (data control subcircuit) can be either edge-triggered (single edge or dual edge), responding to transitions at the clock input, or pulsed, responding to an active level at the clock input. The key distinction of scheme in FIG. 7 from commonly used scannable edge-triggered or pulsed latches with a Set/Reset latch at the second stage is that the scan input is multiplexed with the data signal at the memory subcircuit of the latch (12 in FIG. 7). Such a connection decouples the capacitance introduced by multiplexing the scan and data signals from the glitching activity at the data input, which leads to power reduction, as described above. During the scan mode, the level sensitive scan latch 13 prevents the scan input SCAN_IN from propagating directly to the scan output Q_SCAN, eliminating the possibility for the race conditions in the scan mode. Either single-rail or dual-rail signals can be used to connect latches in a scan chain.

### Detailed Description of the Preferred FET Embodiments

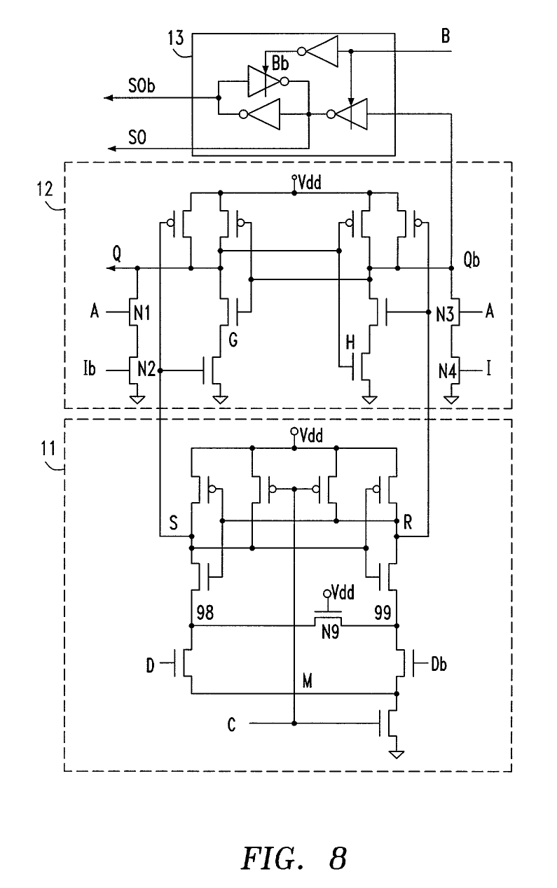

Referring now to FIG. 8 there is shown a sense amplifier latch that provides LSSD compatible design methodology, while significantly reducing the power overhead. The circuit in FIG. 8 is an embodiment of the scannable latch in FIG. 7. The first stage 11 (referred to in the claims as the data control subcircuit) is an edge-triggered circuit that generates Set (S) and Reset (R) signals for the second stage 12. The second stage (referred to in the claims as the memory subcircuit) is a set-reset latch, formed by transistors organized in two cross-coupled NAND circuits.

A low power overhead of the scan mechanism is achieved by mixing in the scan-in data at the memory subcircuit of the latch, R-S stage in FIG. 8, using the level-sensitive write mode, and by employing a small-area level sensitive scan latch 13 at the data scan-out output.

The scan-in signal, I is written to the memory subcircuit through transistors N1 and N2, or N3 and N4 (referred to as the scan control subcircuit). A high level of clock A enables the scan-in write operation. The scan latch 13 is a level sensitive latch controlled by clock B. During the scan mode clock C is kept at the low level, and the memory subcircuit 12 of the latch and the scan latch 13 work as a master-slave latch, controlled by clocks A and B, as required by the LSSD standard. Dual-rail signals for connecting latches in the scan chain are used in this embodiment to reduce the area overhead of the scan mechanism. Single rail connection can be used as well.

During the normal operation mode, clocks A and B are kept at the low level, and the latch operates as a conventional sense amplifier latch. The power overhead of the scan mechanism is reduced to the drain capacitance of two small size transistors N1 and N3, connected to the output nodes Q and Qb. This extra capacitance is charged or discharged at most once per clock cycle, and is not affected by spurious transitions at the data input. Thus, in the inventive latch, the power overhead of the scan mechanism is

P_scan=0.5*f*a*Vdd\hat{ }2*(C_{—}d+C_{—}g)

where C_d is the drain capacitance of transistors N1 and N3 in FIG. 8, C_g is the input gate capacitance of scan latch 13 in FIG. 8 and a is the switching activity at the data input. Thus, the power overhead of the scan mechanism in FIG. 8 is considerably lower than that of the prior art.

Transistor N9 between nodes 98 and 99 is needed for the latch to operate as a STATIC edge triggered flip-flop. Suppose, D=1 and at the rising edge of the clock node 98 goes low, which pulls node S to the ground, which in turn sets the memory subcircuit of the latch to ‘1’. If data input D changes to D=0 while the clock is high, transistor N9 provides a path from node 98 to the ground (through the transistor whose gate is connected to Db). This way node 98 and node S stay at low and node R stays at high while clock is high, independent of (false) transitions, or glitches at the data input. Thus, the latch works as an edge-triggered flip-flop no matter how wide the clock pulse is.

Without transistor N9 between nodes 98 and 99, node 98 would loose the path to the ground if D goes low while clock is high. Then, depending on the balance of the leakage currents, node 98 (and consequently node S) could leak up to a the voltage high enough to enable the path from node R to the ground. This would flip the data control subcircuit 11 of the latch, that is S would go high and R would go low, which in turn would reset the memory subcircuit 12 of the latch to ‘0’. Thus, the flip-flop would be sensitive to glitches at the data input while clock is high. Notice that it would still be a valid latch, if we impose restrictions on how long clock is allowed to be at high. Such a latch is called a semi-static flip-flop in the literature.

Those skilled in the art will appreciate that connecting the scan control circuit directly to the memory circuit reduces the power consumed by glitching at the data input terminals and/or power consumed by precharging the data control subcircuit. Similarly, keeping the data out (Q) terminal separate from the scan out (SO) terminal reduces the power consumed by switching parasitic capacitance of the scan wire.

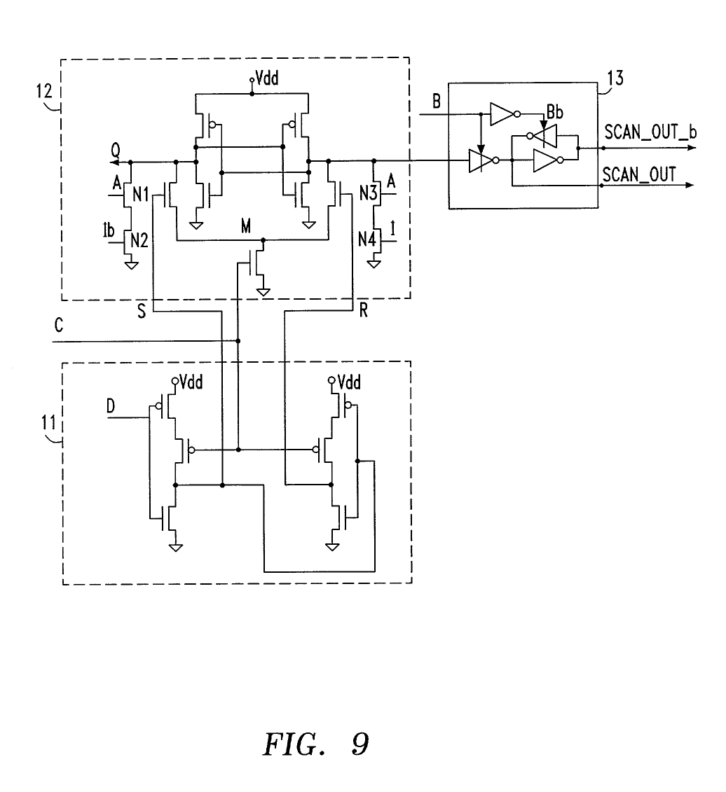

The inventive scan mechanism can be used with a variety of other edge-triggered latches. FIG. 9 shows another embodiment of the scannable latch in FIG. 7, where a true single-phase latch is used at the data control subcircuit 11, and a RAM latch is used for the memory subcircuit 12. Transistors N1, N2, N3 and N4 comprise the scan control subcircuit. Level sensitive latch 13 is the scan latch.

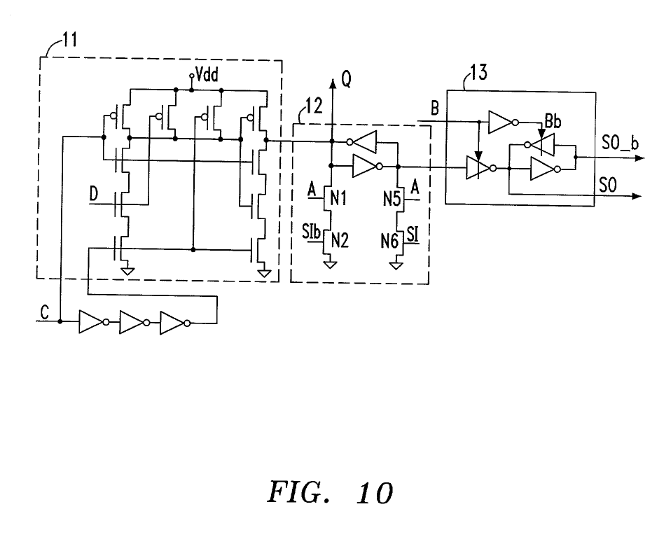

FIG. 10 shows a FET embodiment of the scannable latch in FIG. 6B, with a pulsed latch (known in the literature as HLFF), used for the data control subcircuit 11, and a cross-coupled inverter pair used for the memory subcircuit 12. Transistors N1, N2, N5 and N6 comprise the scan control subcircuit. Level sensitive latch 13 is the scan latch.

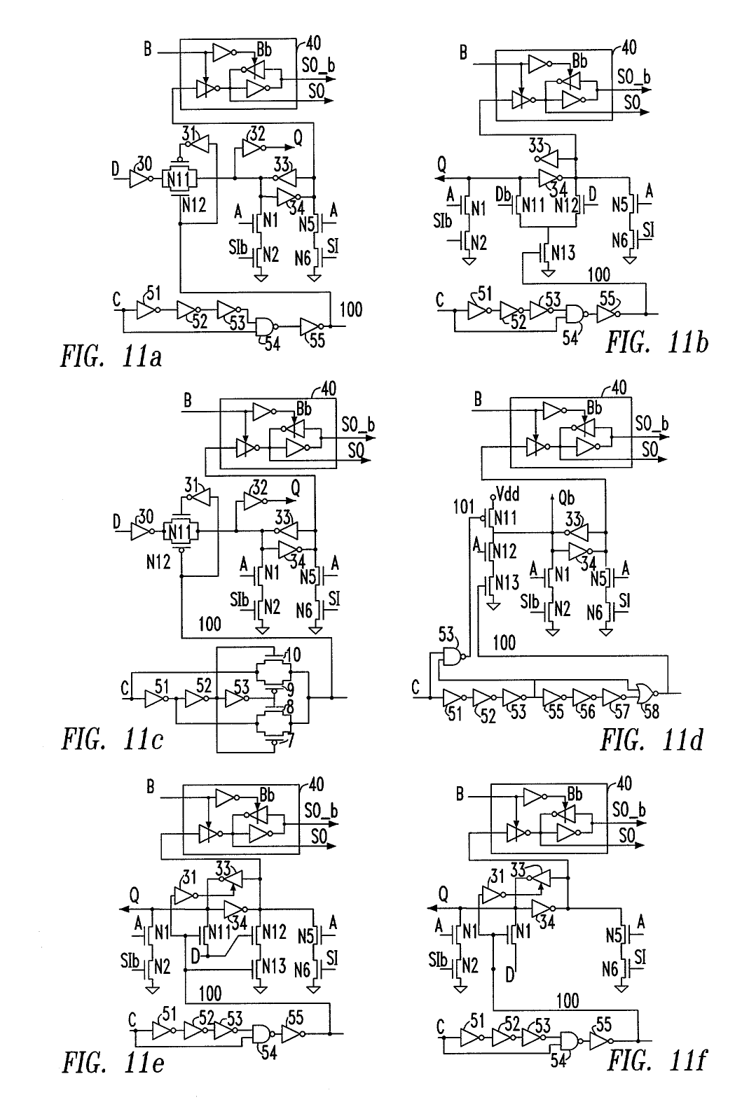

FIG. 11 shows FET circuit embodiments of the scan mechanism of FIG. 6B, with several types of commonly used pulsed flip-flops, including dual-edge flip-flops.

FIG. 11a shows a standard pulsed latch equipped with a scan mechanism according to the invention. The basic pulsed latch in FIG. 11a is formed by the cross coupled inverters 33 and 34 which hold the state of the latch (they form the memory subcircuit of this latch), transistors PFET N11 and NFET N12 forming a transmission gate, which writes new data from the memory subcircuit of the latch, data output driver 32 which provides the output drive capability of the latch, data input inverter 30 which serves to protect the diffusion areas of transistors N11 and N12 (this inverter is sometimes omitted). Transistors N11 and N12 and inverters 30 and 31 form the data control subcircuit. Transistors N1, N2, N5 and N6 form the scan control subcircuit. Inverters 51, 52, 53, 55 and NAND gate 54 form a clock pulse generation circuit which may be shared between several latches. Scan control subcircuit (formed by transistors N1, N2, N5, N6) and level sensitive scan latch 40 comprise the scan mechanism according to the current invention. Although in FIG. 11a the scan signal is passed as a differential signal, a single rail implementation is easily derived from FIG. 11a.

During the normal operation mode clocks A and B are low and the latch works as a conventional pulsed latch: whenever clock C goes high, a pulse is formed at the node 100 whose length is equal to the delay through the inverter chain 51, 52 and 53. During the interval when node 100 is high the data at the data input is written to the memory subcircuit of the latch. During the scan mode clock C is kept at low level and the memory subcircuit, scan control subcircuit and the scan latch 40 work as a master-slave latch controlled by nonoverlapping phases of clocks A and B.

FIG. 11b shows another standard pulsed latch equipped with the inventive scan mechanism. The basic pulsed latch in FIG. 11b is formed by the cross coupled inverters 33 and 34 which hold the state of the latch (they form the memory subcircuit of this latch) and NFET transistors N11, N12 and N13 comprising the data control subcircuit which writes new data from the data inputs D and Db to the memory subcircuit. Inverters 51, 52, 53, 55 and NAND gate 54 form a clock pulse generation circuit which may be shared between several latches. The scan control subcircuit formed by transistors N1, N2, N5, N6 and the level sensitive scan latch 40 comprise the scan mechanism according to the current invention. Although in FIG. 11b the scan signal is passed as a differential signal, a single rail implementation is easily derived from FIG. 11b.

During the normal operation mode clocks A and B are low and the latch works as a conventional pulsed latch: whenever clock C goes high, a pulse is formed at the node 100 whose length is equal to the delay through the inverter chain 51, 52 and 53. During the interval when node 100 is high the data at the data input is written to the memory subcircuit. During the scan mode clock C is kept at low level and the memory subcircuit, scan control subcircuit and the scan latch 40 work as a master-slave latch controlled by nonoverlapping phases of clocks A and B.

FIG. 11c shows a double-edge triggered pulsed latch equipped with the scan mechanism. The basic double-edge triggered pulsed latch in FIG. 11c is formed by the cross coupled inverters 33 and 34 which hold the state of the latch (they form the memory subcircuit of this latch), transistors NFET N11 and PFET N12 forming a transmission gate, which writes new data from the data input to the memory subcircuit, data output driver 32 which provides the output drive capability of the latch, data input inverter 30 which serves to protect the diffusion areas of transistors N11 and N12 (this inverter is sometimes omitted). Transistors N11 and N12 and inverters 30 and 31 form the data control subcircuit. Transistors N1, N2, N5 and N6 form the scan control subcircuit. Inverters 51, 52, 53 and transmission gates formed by transistors 7 8 9 and 10 form a clock pulse generation circuit which may be shared between several latches. Unlike the standard pulsed latch in FIG. 11a a negative pulse at node 100 is generated on both rising and falling edges of the clock. The scan control subcircuit, formed by transistors N1, N2, N5, N6 and level sensitive scan latch 40 comprise the scan mechanism according to the current invention. Although in FIG. 11c the scan signal is passed as a differential signal, a single rail implementation is easily derived from FIG. 11c.

During the normal operation mode clocks A and B are low and the latch works as a double-edge triggered pulsed latch: whenever clock C goes high or low, a negative pulse is formed at the node 100 whose length is equal to the delay through the inverter chain 51, 52 and 53. During the interval when node 100 is low the data at the data input is written to the memory subcircuit of the latch. During the scan mode clock C is kept at low level and the scan control subcircuit, memory subcircuit and the scan latch 40 work as a master-slave latch controlled by nonoverlapping phases of clocks A and B.

FIG. 11d shows a precharged pulsed latch equipped with the inventive scan mechanism. The basic pulsed latch in FIG. 11d is formed by the cross coupled inverters 33 and 34 which hold the state of the latch (they form the memory subcircuit), transistors NFET N12, N13 and PFET N11 writes new data from the data input to the memory subcircuit. The form the data control subcircuit. Inverters 51, 52, 53, 55, 56, 57, NAND gate 54 and NOR gate 58 form a clock pulse generation circuit which may be shared between several latches. Scan control subcircuit, formed by transistors N1, N2, N5, N6 and level sensitive scan latch 40 comprise the scan mechanism according to the current invention. Although in FIG. 11d the scan signal is passed as a differential signal, a single rail implementation is easily derived from FIG. 11d.

During the normal operation mode clocks A and B are low and the latch works as a conventional precharged pulsed latch: whenever clock C goes high, first a negative pulse is formed at the node 101 whose length is equal to the delay through the inverter chain 51, 52 and 53. During the interval when node 101 is low the second stage of the latch is precharged to ‘1’ through PFET transistor N11. Then a positive pulse is formed at the node 100 whose length is equal to the delay through the inverter chain 55, 56 and 57. During the interval when node 100 is high the data at the data input is written to the memory subcircuit of the latch (formed by inverters 33 and 34). During the scan mode clock C is kept at low level and the scan control subcircuit, memory subcircuit and the scan latch 40 work as a master-slave latch controlled by nonoverlapping phases of clocks A and B.

FIG. 11e shows a mixed-input pulsed latch equipped with the scan mechanism. The basic pulsed latch in FIG. 11e is formed by the cross coupled inverter 34 and 33 which hold the state of the latch (they form the memory subcircuit), data control subcircuit, formed by transistors NFET N11 N12 and N13 which writes new data from the data input to the memory subcircuit. Inverters 51, 52, 53, 55 and NAND gate 54 form a clock pulse generation circuit which may be shared between several latches. Scan control subcircuit, formed by transistors N1, N2, N5, N6 and level sensitive scan latch 40 comprise the scan mechanism according to the current invention. Although in FIG. 11e the scan signal is passed as a differential signal, a single rail implementation is easily derived from FIG. 11e.

During the normal operation mode clocks A and B are low and the latch works as a conventional pulsed latch: whenever clock C goes high, a pulse is formed at the node 100 whose length is equal to the delay through the inverter chain 51, 52 and 53. During the interval when node 100 is high the data at the data input is written to the memory subcircuit of the latch through the data control subcircuit. During the scan mode clock C is kept at low level and the scan control subcircuit, memory subcircuit and the scan latch 40 work as a master-slave latch controlled by nonoverlapping phases of clocks A and B.

FIG. 11f shows another version of a pulsed latch equipped with the inventive scan mechanism. The basic pulsed latch in FIG. 11e is formed by the cross coupled inverter 34 and inverter 33 with a control transistor in the NFET stack to disable the path from the output node of the inverter to the ground, which hold the state of the latch (these inverters 33 and 34 form the memory subcircuit), and transistor NFET N11 which writes new data from the data input to the second stage of the latch. Transistor N11 and inverter 31 form the data control subcircuit. Inverters 51, 52, 53, 55 and NAND gate 54 form a clock pulse generation circuit which may be shared between several latches. The scan control subcircuit formed by transistors N1, N2, N5, N6 and level sensitive scan latch 40 comprise the scan mechanism according to the current invention. Although in FIG. 11e the scan signal is passed as a differential signal, a single rail implementation is easily derived from FIG. 11e.

During the normal operation mode clocks A and B are low and the latch works as a conventional pulsed latch: whenever clock C goes high, a pulse is formed at the node 100 whose length is equal to the delay through the inverter chain 51, 52 and 53. During the interval when node 100 is high the data at the data input is written to the memory subcircuit of the latch. Since the path to the ground in the feedback inverter 33 is disabled when node 100 is high, both high and low levels at the data input can be written in the second stage of the latch. During the scan mode clock C is kept at low level and the scan control subcircuit, memory subcircuit and the scan latch 40 work as a master-slave latch controlled by nonoverlapping phases of clocks A and B.

While there has been described and illustrated a low power flip-flop having Level Sensitive Scan Design (LSSD) capability, it will be apparent to those skilled in the art that modifications and variations are possible without deviating from the broad scope of the invention which shall be limited solely by the scope of the claims appended hereto.

Having thus described our invention, what we claim as new and desire to secure by Letters Patent is:

1. A scannable latch comprising a main latch and a scan latch for controllably passing data down at least one scan chain during a scan mode, said main latch having a data input terminal, a data out terminal, at least one clock terminal, a scan in terminal and a scan control terminal said main latch further comprising:
a memory subcircuit for holding data at said data output terminal that switches at most once per clock cycle during the normal operation mode;
a data control subcircuit connected to said data input terminal for overwriting the state of said memory subcircuit in response to a signal on said data input; and
a scan control subcircuit responsive to said scan input terminal and said scan control terminal for overwriting the state of said memory subcircuit in response to a scan control signal and connected directly to said memory subcircuit, whereby the introduced capacitance of said scan control subcircuit switches at most once per clock cycle during the normal operation mode.

2. A scannable latch comprising a main latch and a scan latch for controllably passing data from a scan out terminal down at least one scan chain during a scan mode, said main latch having a data in terminal, at least one data out terminal electrically separated from said scan out terminal, at least one clock terminal, scan in terminal and scan control terminal in which said main latch consists of a memory subcircuit connected to said data output terminal of the latch, said scan in terminal and said scan control terminal for holding data at said data output of the latch that switches at most once in one clock cycle during the normal operation mode and which has means for changing the state of said data in response to transitions at said scan input and scan control terminals, so that the parasitic capacitance of transistors that change the state of said memory subcircuit switches at most once per clock cycle during the normal operation mode, thereby reducing the power overhead of the scan mechanism; and a subcircuit connected to the said data input of the latch and one or two said clock inputs for overwriting the state of said memory subcircuit in response to appropriate transitions at the said data and clock input terminals.

3. A latch according to claim 1 in which said data control subcircuit and said memory subcircuit are configured to operate as a single-phase latch in the normal mode, and in which said scan control and memory subcircuits and said scan latch are configured to operate as a master-slave latch during said scan mode.

4. A latch according to claim 2, in which said data control subcircuit and said memory subcircuit are configured to operate as a single-phase latch in the normal mode, and in which said memory subcircuit and said scan latch are configured to operate as a master-slave latch during said scan mode.

5. A latch according to claim 3, in which said scan control and memory subcircuits and said scan latch are configured to operate during said scan mode as a master-slave latch with two nonoverlapping clocks.

6. A latch according to claim 4, in which said memory subcircuit and said scan latch are configured to operate during said scan mode as a master-slave latch with two nonoverlapping clocks.

7. A latch according to claim 1 in which said data control subcircuit and said memory subcircuit are configured to operate as a two-phase master-slave latch in the normal mode, and in which said scan control and memory subcircuits and said scan latch are configured to operate as a master-slave latch during said scan mode.

8. A latch according to claim 2 in which said data control subcircuit and said memory subcircuit are configured to operate as a two-phase master-slave latch in the normal mode, and in which said memory subcircuit and said scan latch are configured to operate as a master-slave latch during said scan mode.

9. A latch according to claim 1 in which said data control subcircuit and said memory subcircuit are configured to operate as a pulsed latch, and in which said scan control and memory subcircuits and said scan latch are configured to operate as a master-slave latch during said scan mode.

10. A latch according to claim 2 in which said data control subcircuit and said memory subcircuit are configured to operate as a pulsed latch, and in which said memory subcircuit and said scan latch are configured to operate as a master-slave latch during said scan mode.
